(19) United States
(12) Patent Application Publication
(10) Pub. No.: US 2016/0314224 A1
(43) Pub. Date: Oct. 27, 2016

(54) AUTONOMOUS VEHICLE SIMULATION SYSTEM

(71) Applicants: JEROME H. WEI, LA HABRA, CA (US); WALTER WANG, HACIENDA HEIGHTS, CA (US); ARTHUR GEVORKIAN, LOS ANGELES, CA (US)

(72) Inventors: JEROME H. WEI, LA HABRA, CA (US); WALTER WANG, HACIENDA HEIGHTS, CA (US); ARTHUR GEVORKIAN, LOS ANGELES, CA (US)

(73) Assignee: NORTHROP GRUMMAN SYSTEMS CORPORATION, FALLS CHURCH, VA (US)

(21) Appl. No.: 14/695,495

(22) Filed: Apr. 24, 2015

(51) Int. Cl. G06F 17/50; G05D 1/00

(52) U.S. Cl. CPC G06F 17/5009; G05D 1/0088

(57) ABSTRACT

One embodiment includes a simulation system for an autonomous vehicle. The simulation system includes a user interface configured to facilitate user inputs comprising spontaneous simulated events in a simulated virtual environment during simulated operation of the autonomous vehicle via an autonomous vehicle control system. The system also includes a simulation controller configured to generate simulated sensor data based on model data and behavioral data associated with each of the simulated virtual environment and the spontaneous simulated events. The simulated sensor data corresponds to simulated sensor inputs provided to the autonomous vehicle control system via sensors of the autonomous vehicle. The simulation controller is further configured to receive simulation feedback data from the autonomous vehicle control system corresponding to simulated interaction of the autonomous vehicle within the simulated virtual environment. The simulated interaction includes reactive behavior of the autonomous vehicle control system in response to the spontaneous simulated events.

### TECHNICAL FIELD

The present invention relates generally to computer test systems, and specifically to an autonomous vehicle simulation system.

### BACKGROUND

Unmanned vehicles are becoming increasingly more common in a number of tactical missions, such as in surveillance and/or combat missions. As an example, in the case of aircraft, as some flight operations became increasingly more dangerous or tedious, unmanned aerial vehicles (UAV) have been developed as a means for replacing pilots in the aircraft for controlling the aircraft. Furthermore, as computer processing and sensor technology has advanced significantly, unmanned vehicles can be operated in an autonomous manner. For example, a given unmanned vehicle can be operated based on sensors configured to monitor external stimuli, and can be programmed to respond to the external stimuli and to execute mission objectives that are either programmed or provided as input commands, as opposed to being operated by a remote pilot.

### SUMMARY

One embodiment includes a simulation system for an autonomous vehicle. The simulation system includes a user interface configured to facilitate user inputs comprising spontaneous simulated events in a simulated virtual environment during simulated operation of the autonomous vehicle via an autonomous vehicle control system. The system also includes a simulation controller configured to generate simulated sensor data based on model data and behavioral data associated with each of the simulated virtual environment and the spontaneous simulated events. The simulated sensor data corresponds to simulated sensor inputs provided to the autonomous vehicle control system via sensors of the autonomous vehicle. The simulation controller is further configured to receive simulation feedback data from the autonomous vehicle control system corresponding to simulated interaction of the autonomous vehicle within the simulated virtual environment. The simulated interaction includes reactive behavior of the autonomous vehicle control system in response to the spontaneous simulated events.

Another embodiment includes a method for simulating a mission for an autonomous vehicle. The method includes storing model data and behavioral data associated with a simulated virtual environment and receiving control inputs via a user interface for control of simulated interaction of the autonomous vehicle in the simulated virtual environment. The method also includes providing control commands to an autonomous vehicle control system for control of the simulated interaction of the autonomous vehicle in the simulated virtual environment based on the control inputs. The method also includes receiving an event input via the user interface corresponding to a spontaneous simulated event in the simulated virtual environment during the simulated mission of the autonomous vehicle. The method also includes integrating the spontaneous simulated event into the simulated virtual environment based on the model and behavioral data associated with each of a simulated virtual environment and the autonomous vehicle and model data and behavioral data associated with the spontaneous simulated event. The method also includes providing simulated sensor data to the autonomous vehicle control system based on the model data and the behavioral data associated with each of the simulated virtual environment and the spontaneous simulated event. The method further includes providing simulation feedback data from the autonomous vehicle control system comprising the simulated interaction of the autonomous vehicle within the simulated virtual environment and reactive behavior of the autonomous vehicle control system in response to the spontaneous simulated event to the user interface.

Another embodiment includes a simulation system for an autonomous vehicle. The simulation system includes a user interface configured to facilitate user inputs comprising spontaneous simulated events in a simulated virtual environment during simulated operation of the autonomous vehicle via an autonomous vehicle control system, and to record a simulated interaction of the autonomous vehicle in the simulated virtual environment to generate an event log comprising a simulated mission of the autonomous vehicle. The system also includes a simulation controller. The simulation controller includes a memory configured to store model data and behavior data associated with the simulated virtual environment. The simulation controller also includes a simulation driver configured to generate at least one event entity based on the model data, the behavioral data, the user inputs, and a clock signal; to integrate the at least one event entity into the simulated virtual environment; to provide simulated sensor data based on the model and behavioral data associated with each of the simulated virtual environment and the at least one event entity, and to receive simulation feedback data from the autonomous vehicle control system corresponding to the simulated interaction of the autonomous vehicle within the simulated virtual environment. The simulated interaction includes reactive behavior of the autonomous vehicle control system in response to the at least one event entity.

### BRIEF DESCRIPTION OF THE DRAWINGS

FIG. 1 illustrates an example of an autonomous vehicle simulation system.

FIG. 2 illustrates an example of a memory system.

FIG. 3 illustrates an example diagram of a geographic scene.

FIG. 4 illustrates an example of a dynamic object.

FIG. 5 illustrates an example of another example of a geographic scene.

FIG. 6 illustrates an example of a user interface.

FIG. 7 illustrates an example of a simulation driver.

FIG. 8 illustrates an example of a method for simulating a mission for an autonomous vehicle.

### DETAILED DESCRIPTION

The present invention relates generally to computer test systems, and specifically to an autonomous vehicle simulation system. An autonomous vehicle simulation system includes a user interface configured to facilitate user inputs for the simulation system and a simulation controller configured to implement a simulated mission for the autonomous vehicle. The user inputs can include model inputs to generate simulation models associated with a simulated virtual environment, dynamic objects (e.g., static object and traffic entities), environmental factors (e.g., simulated weather conditions), and sensors associated with the autonomous vehicle. For example, the simulation controller can include a memory configured to store the model data, as well as behavioral data associated with dynamic objects, the autonomous vehicle, and physical interactions of the components of the simulation. The user inputs can also include control commands that can provide simple operational commands (e.g., air traffic control commands in the example of an autonomous aircraft) to an autonomous vehicle control system of the autonomous vehicle (e.g., takeoff, land, target a specific object, etc.). As an example, the control commands can be provided as voice inputs via a voice control interface of the user interface that can be configured to convert voice inputs into the control commands for interpretation by the autonomous vehicle control system and to convert operational feedback signals as voice acknowledgements to be interpreted by the user.

In addition, the user interface can be configured to facilitate event inputs associated with spontaneous simulated events. As an example, the spontaneous simulated events can be spontaneous perturbations of the simulated virtual environment, such as to force reactive behavior of the autonomous vehicle control system in the simulated interaction of the autonomous vehicle in the simulated virtual environment. For example, the spontaneous simulated events can correspond to behavioral changes associated with dynamic objects, such as simulated vehicles in the simulated virtual environment, and/or changes to environmental conditions (e.g., simulated weather conditions) in the simulated virtual environment. The simulation controller can include a simulation driver configured to generate event entities in response to the event inputs and to integrate the event inputs into the simulated virtual environment to elicit a simulated improvised behavioral response of the autonomous vehicle in response to the spontaneous simulated event. The simulation controller can receive feedback signals from the autonomous vehicle control system to monitor the simulated interaction of the autonomous vehicle in the simulated virtual environment, such that the simulated interaction can be monitored via the user interface and/or recorded in an event log corresponding to a simulated mission for the autonomous vehicle. Accordingly, the autonomous vehicle can be tested based on monitoring reactive behavioral in a simulated mission in response to the user provided spontaneous simulated events.

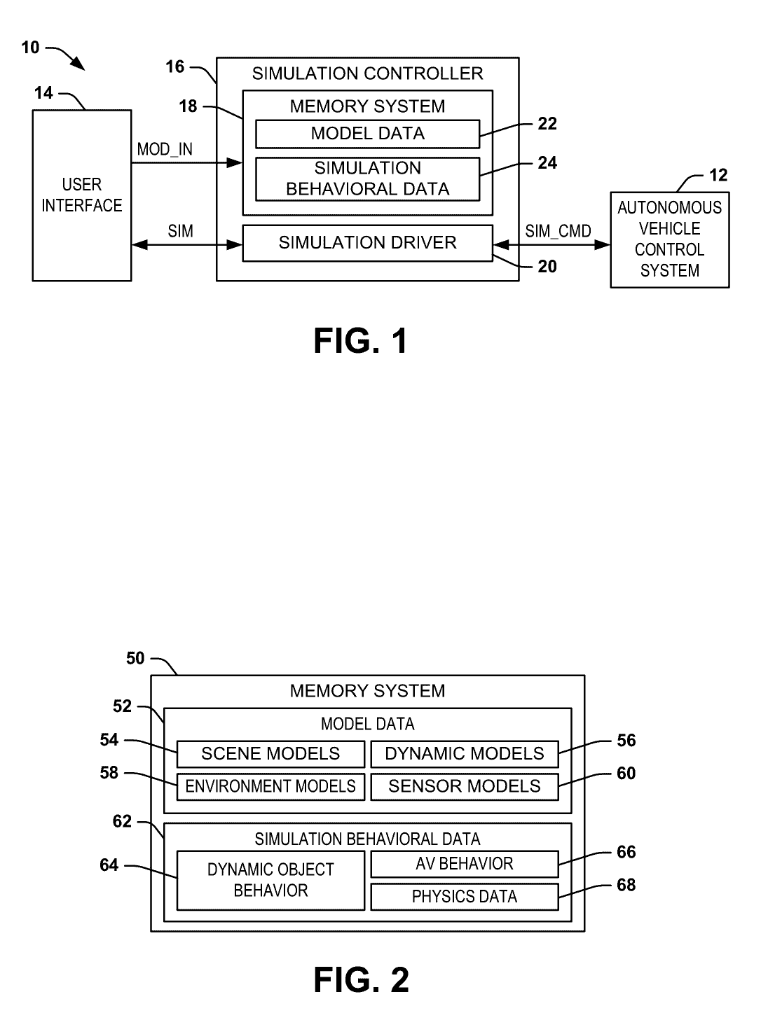

FIG. 1 illustrates an example of an autonomous vehicle simulation system 10. The autonomous vehicle simulation system 10 is configured to implement simulated missions of an autonomous vehicle. As described herein, the term “autonomous vehicle” describes an unmanned vehicle that operates in an autonomous manner, such that the autonomous vehicle is not piloted or operated in any continuous manner, but instead operates continuously based on a programmed set of instructions that dictate motion, maneuverability, and the execution of actions directed toward completing mission objectives. As an example, the autonomous vehicle can be configured as an unmanned aerial vehicle (UAV) that operates in an autonomous robotic manner for any of a variety of different purposes. Therefore, the autonomous vehicle simulation system 10 is configured to test the autonomous operation of the autonomous vehicle in a simulated manner, such that the autonomous vehicle is not tested in a real-world environment that can result in high-cost failures.

The autonomous vehicle simulation system 10 includes an autonomous vehicle control system 12 that is configured as an operational controller for the associated autonomous vehicle, and is therefore the component of the autonomous vehicle that is to be tested for autonomous operation of the associated autonomous vehicle in a simulated manner, as described herein. As an example, the autonomous vehicle control system 12 can be configured as one or more processors that are configured to receive inputs from sensors associated with the autonomous vehicle and provide outputs to operational components of the autonomous vehicle. The autonomous vehicle control system 12 can thus be tested for autonomous operation of the autonomous vehicle in a simulated mission based on inputs provided to and feedback provided from the autonomous vehicle control system 12. As described herein, the terms “simulated mission” and “simulation of the autonomous vehicle” describe a simulation operation of the autonomous vehicle control system in a simulated virtual environment in which a simulated version of the autonomous vehicle interacts with the simulated virtual environment based on the inputs provided to and the feedback provided from the autonomous vehicle control system 12. Therefore, during a simulated mission, the autonomous vehicle control system 12 may be disconnected from the autonomous vehicle itself, such that the input signals to and feedback signals from the autonomous vehicle control system 12 may be isolated from the respective sensors and operational components of the associated autonomous vehicle.

The autonomous vehicle simulation system 10 also includes a user interface 14 that is configured to facilitate control inputs to provide control commands to the associated autonomous vehicle and to facilitate simulation inputs associated with simulating the operation of the autonomous vehicle. As described herein, the term “control command” describes simple operating commands of the autonomous vehicle that can be provided during the simulated mission, such as for driving, takeoff, landing, turning, targeting, etc., such as in the same manner that an air traffic controller interacts with a piloted vehicle, and does not refer to continuous piloting of the autonomous vehicle. The user interface 14 is also configured to monitor the simulation of the autonomous vehicle, such that a user of the user interface 14 can determine success or failure of a given simulated mission, can provide inputs to the autonomous vehicle control system 12 during an associated simulated mission, and can store the results of a given simulated mission in an event log associated with the simulated mission. In the example of FIG. 1, the inputs provided from and received by the user interface 14 are demonstrated as a bidirectional signal SIM that can correspond to a plurality of different signal media (e.g., wired, wireless, and/or optical signal media). The autonomous vehicle simulation system 10 further includes a simulation controller 16 that is configured to receive and provide the signals SIM to and from the user interface 14. The simulation controller 16 is also configured to provide simulation signals to and receive simulation feedback signals from the autonomous vehicle control system 12, demonstrated in the example of FIG. 1 as signals SIM_CMD. The simulation controller 16 is thus configured as an interface between the user interface 14 and the autonomous vehicle control system 12 to implement simulation of the autonomous vehicle.

The simulation controller 16 includes a memory system 18 and a simulation driver 20. The memory system 18 can be arranged as one or more memory structures or devices configured to store data associated with the simulation of the autonomous vehicle. Additionally, the memory system 18 can be configured to store a variety of other data and data files, such as stored logs of simulated missions of the autonomous vehicle. In the example of FIG. 1, the memory system 18 includes model data 22 and simulation behavioral data 24. The model data 22 can include data associated with simulated renderings of the simulated virtual environment in which the simulated version of the autonomous vehicle interacts in a given simulated mission. For example, the model data 22 can include data associated with the static physical features of the simulated virtual environment corresponding to a rendered three-dimensional geographic scene of interest (e.g., topographical features, buildings, roads, bodies of water, etc.), data associated with one or more dynamic models (e.g., moving objects, such as people, other vehicles, ballistic threats, etc.), data associated with environmental conditions (e.g., weather conditions that can affect sensors and/or performance of the autonomous vehicle, etc.), and data associated with the sensors of the autonomous vehicle, such as can be modeled to simulate sensor responses of actual hardware sensors associated with the autonomous vehicle to transform conditions of the simulated virtual environment into actual sensor data. As another example, the simulation behavioral data 24 can include data associated with behavior of the dynamic objects in the simulated virtual environment (e.g., motion of vehicles), data associated with the autonomous vehicle, such as including physical characteristics of the autonomous vehicle and the interaction of the actuators of the autonomous vehicle in the simulated virtual environment, and can include physics data that can define physical interactions of substantially all components of the simulated virtual environment. As an example, the physics data can be generated via a physics engine, such as including one or more processors associated with the simulation controller 16, or can be stored in the memory system 18. The model data 22 and the simulation behavioral data 24 can be programmable, such as defined by a user via the user interface 14. In the example of FIG. 1, the user interface 14 can be configured to facilitate inputs to allow a user to define and/or modify the model data 22 and/or the simulation behavioral data 24 via signals MOD_IN that are provided to the memory system 18.

The simulation driver 20 is configured to integrate the simulation inputs SIM provided via the user interface 14 with the model data 22 and the simulation behavioral data 24 to provide the simulation commands SIM_CMD to the autonomous vehicle control system 12. Additionally, the simulation driver 20 is configured to receive the feedback signals SIM_CMD from the autonomous vehicle control system 12 to update the conditions and status of the simulated mission, and to provide the feedback signals SIM to the user interface 14 to allow the user to monitor the simulated mission via the user interface 14. As an example, the simulation driver 20 can be configured as one or more processors configured to compile the simulated mission. Therefore, the simulation driver 20 is configured to facilitate the simulation of the autonomous vehicle in a manner that is safer and less expensive than live real-world testing of the autonomous vehicle.

FIG. 2 illustrates an example of a memory system 50. The memory system 50 can correspond to the memory system 18 in the example of FIG. 1. Therefore, reference is to be made to the example of FIG. 1 in the following description of the example of FIG. 2.

The memory system 50 can be arranged as one or more memory structures or devices configured to store data associated with the simulation of the autonomous vehicle. Additionally, the memory system 50 can be configured to store a variety of other data and data files, such as stored logs of simulated missions of the autonomous vehicle. In the example of FIG. 2, the memory system 50 includes model data 52. The model data 52 includes scene models 54 that can include model data associated with the physical attributes and confines of the simulated virtual environment. As an example, the simulated virtual environment can include any of a variety of geographic regions that can correspond to real locations or locations that have been created via the user interface 14. As described by example herein, the simulated virtual environment can have a setting of an airport, such as Hawthorne Municipal Airport (KHHR) in Hawthorne, Calif. The scene models 54 can thus include data associated with simulated renderings of the simulated virtual environment in which the simulated version of the autonomous vehicle interacts in a given simulated mission. For example, the scene models 54 can include data defining static physical features and boundaries of the geographic scene of interest associated with the simulated virtual environment, such as in a rendered three-dimensional manner. Thus, the scene models 54 can define a three-dimensional physical rendering of topographical features, buildings, roads, bodies of water, boundaries associated with the edges of the simulated virtual environment, and any of a variety of other static features of the simulated virtual environment.

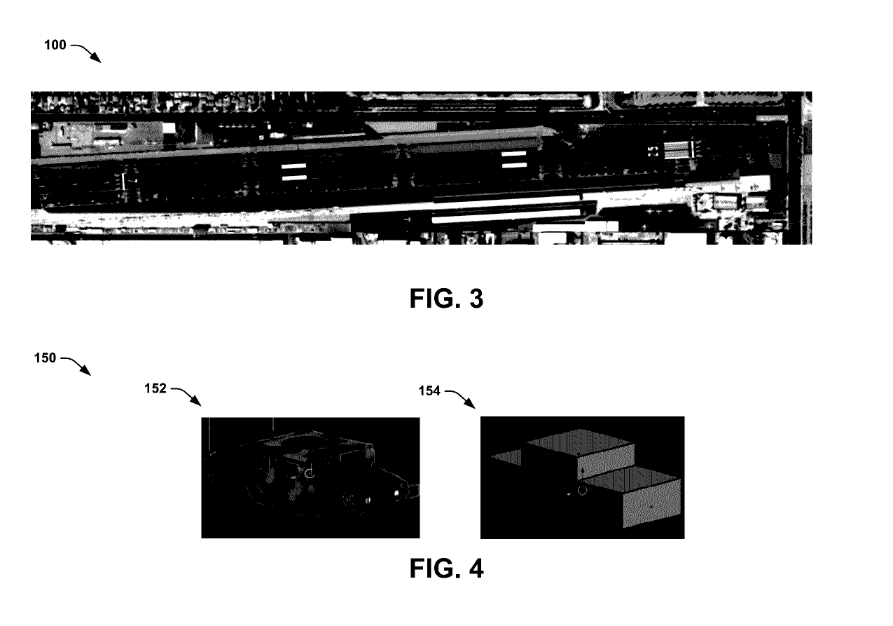

FIG. 3 illustrates an example diagram 100 of a geographic scene. The diagram 100 includes an overhead view of the geographic scene, demonstrated as Hawthorne Municipal Airport. The diagram 100 can correspond to an actual still image of the geographic scene in an overhead view. As described in greater detail herein, in a real-world (i.e., non-simulated) mission, the autonomous vehicle can implement the electro-optical imaging sensors to capture images of the geographic scene in real-time and provide the images to one or more users (e.g., wirelessly) in real-time. Conversely, in the simulated virtual environment, a user can generate the scene of interest in a three-dimensional rendering to enable the simulated version of the autonomous vehicle to interact with the simulated virtual environment. As an example, the overhead view demonstrated in the diagram 100 can be implemented to monitor the simulated mission via the user interface 14, such as in one of a plurality of different selective views, such as in an overhead view of the three-dimensionally rendered simulated virtual environment, or as simulated objects superimposed onto an overhead view of an actual image of the geographic scene.

As an example, to provide traceability between simulation and real world testing, the target demonstration environment of the scene of interest (e.g., Hawthorne Municipal Airport in the example of FIG. 3) can be recreated virtually in the simulation environment. For example, high definition satellite imagery can be implemented for texture mapping of the ground surface of the geographic scene of interest, and buildings and other features of the geographic scene of interest can be added by implementing online tools (e.g., Google Maps™) and/or on-site survey. Developed scripts can be implemented to incorporate and associate operational information associated with the geographic scene of interest into a given parseable dataset associated with the simulated virtual environment to provide an accurate detailed rendering of the geographic scene of interest. As described in greater detail herein, the outlines of the static structures and features (e.g., topography and building dimensions) can be accurately and in-scale described in the scene models 54 in the memory system 50. Therefore, the behavior and performance of the autonomous vehicle can be accurately tested based on the interaction of the simulated version of the autonomous vehicle in the simulated virtual environment.

Referring back to the example of FIG. 2, the model data 52 also includes dynamic models 56 that can define physical characteristics of dynamic objects in the simulated virtual environment. As described herein, the term “dynamic object” any of a variety of objects in the simulated virtual environment that move relative to the static features of the geographic scene of interest. Examples of dynamic objects can include people, vehicles, ballistic objects (e.g., missiles, bombs, or other weapons), or a variety of other types of moving objects. The dynamic models 56 thus define physical boundaries and characteristics of the dynamic objects in the simulated virtual environment, and thus relative to the static features of the simulated virtual environment as the dynamic objects move.

FIG. 4 illustrates an example diagram 150 of a dynamic object. In the example of FIG. 4, the dynamic object is demonstrated as a land vehicle (e.g., a humvee). The diagram 150 includes a first view 152 of the dynamic object and includes a second view 154 of the dynamic object. The first view 152 can correspond to an image of the dynamic object in a user-recognizable manner. As an example, the first view 152 can correspond to a graphical rendering, an icon, or a video image, such as can be provided via a camera and/or other types of electro-optical imaging sensors (e.g., radar, lidar, or a combination thereof). For example, various texture mapped mesh models can be associated with the dynamic object. As another example, in a real-world (i.e., non-simulated) mission, the autonomous vehicle can implement the electro-optical imaging sensors to capture images of the simulated virtual environment in real-time and provide the images to one or more users (e.g., wirelessly) in real-time. Thus, the first view 152 can be implemented for display to a user of the user interface 14 to provide a more realistic and detailed representations of the dynamic objects as detected by electro-optic sensors of the autonomous vehicle.

The second view 154 of the dynamic object corresponds to a dynamic object model demonstrating an approximate outline of the physical boundaries of the dynamic object. As an example, the dynamic object model can be generated by a user via the user interface 14 and can be stored in the memory system 50 as one of the dynamic models 56. The dynamic object model demonstrated by the second view 154 thus corresponds to physical features and characteristics of the dynamic object as functionally interpreted by the simulation controller 16, such as via the simulation driver 20. Thus, the simulation controller 16 can implement the physical boundaries and characteristics of the dynamic object model as a means of interaction of the autonomous vehicle and/or the operational and functional aspects of the autonomous vehicle with the dynamic object. For example, the dynamic object model can be used to define collisions of the dynamic object with the simulated version of the autonomous vehicle, simulated ordnance of the autonomous vehicle, and/or other dynamic objects in the simulated virtual environment. As an example, the simulation driver 20 can be configured to generate an event entity associated with the dynamic object, such that the dynamic object can be controlled within the simulated virtual environment based on the dynamic object model information stored in the dynamic models 56, as well as simulation behavioral data and timing data, as described in greater detail herein.

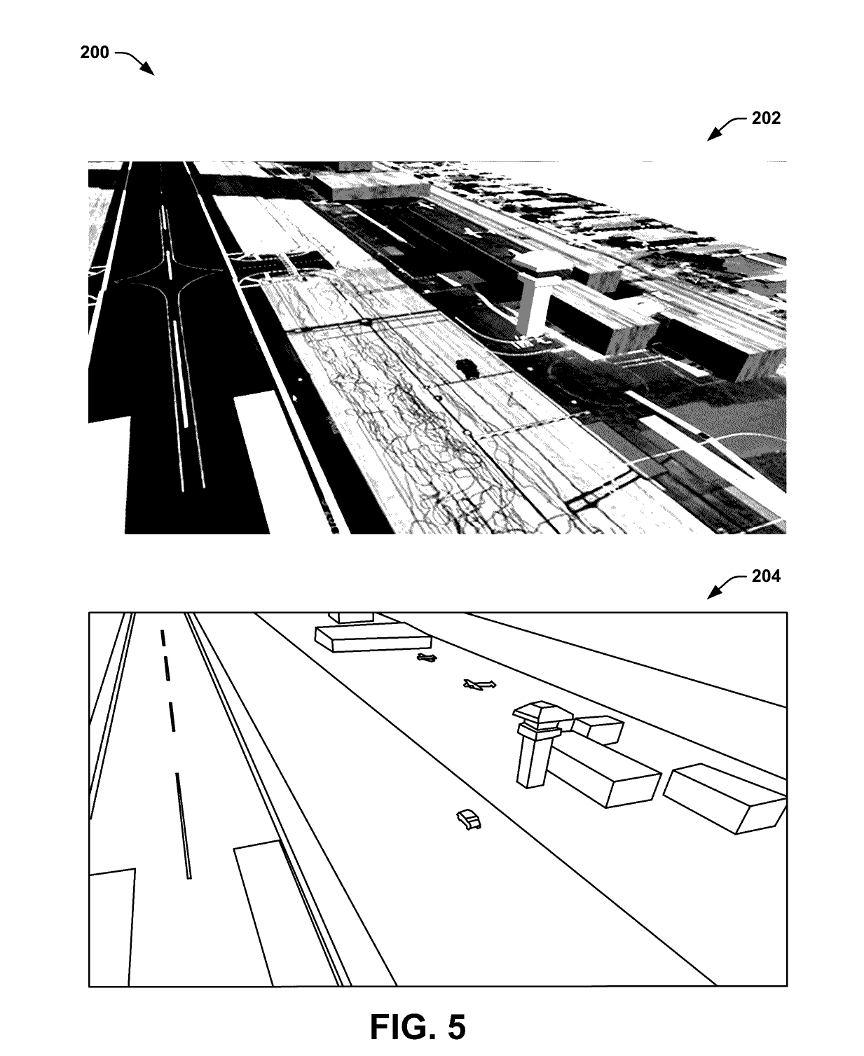

FIG. 5 illustrates an example diagram 200 of a geographic scene. The diagram 200 includes a first view 202 of the geographic scene and includes a second view 204 of the geographic scene. The first scene 202 can correspond to an actual video image of the geographic scene, such as can be provided via a camera and/or other types of electro-optical imaging sensors (e.g., radar, lidar, or a combination thereof), or can correspond to three-dimensional graphical rendering that is implemented for user recognition. As an example, in a real-world (i.e., non-simulated) mission, the autonomous vehicle can implement the electro-optical imaging sensors to capture images of the geographic scene in real-time and provide the images to one or more users (e.g., wirelessly) in real-time. Conversely, in the simulated virtual environment, a user can generate the scene of interest based on the model data 52 (e.g., the scene models 54 and the dynamic models 56) to enable the simulated version of the autonomous vehicle to interact with the simulated virtual environment.

The second view 204 corresponds to the modeling of the simulated virtual environment, and thus a combination of the scene models 54 and the dynamic models 56. Thus, the second view 204 demonstrates an approximate outline of the physical boundaries of the static features of the geographic scene of interest and the dynamic objects therein, such as interpreted by the simulation driver 20. It is to be understood that the second view 204 is demonstrated as a conceptual diagram with respect to the model data 52, and is not necessarily a “view” that is provided to users. As an example, the simulated virtual environment can be generated by the simulation driver 20 based on the model inputs MOD_IN provided by a user via the user interface 14 and stored in the memory system 50 as the respective scene models 54 and the dynamic models 56. In the example of FIG. 5, the simulated virtual environment demonstrated in the second view 204 includes static features 206 corresponding to buildings having three-dimensional modeled boundaries, as described by the scene models 54. The simulated virtual environment demonstrated in the second view 204 also includes dynamic objects 208 corresponding to vehicles (e.g., a ground vehicle and two grounded aerial vehicles in the example of FIG. 5) having three-dimensional modeled boundaries, as described by the dynamic models 56. It is to be understood that the second view 204 may not include every aspect of a given actual geographic scene of interest, such that the scene models 54 and the dynamic models 56 can omit irrelevant details (e.g., distant buildings and terrain features) of the simulated virtual environment to provide for data storage and processing efficiency of the simulated mission.

As the autonomous vehicle moves relative to the static features of the geographic scene of interest, the first view 202 and the second view 204 can each be updated in real-time. As an example, the first view 202 can be updated in real-time for display to user(s) via the user interface 14, such as to simulate the view of the geographic scene of interest that is provided via one or more sensors (e.g., video, radar, lidar, or a combination thereof) to assist in providing control commands to the autonomous vehicle during the simulated mission and/or to monitor progress of the simulated mission in real-time. Similarly, the second view 204 can be updated by the simulation driver 20 to provide constant updates of the relative position of the simulated version of the autonomous vehicle with the static features and the dynamic objects of the simulated virtual environment, as well as the dynamic objects with respect to the static features and with respect to each other, as dictated by the scene models 54 and the dynamic models 56 and the associated simulation behavioral data described herein. Accordingly, the simulation driver 20 can be configured to update the location of the simulated version of the autonomous vehicle and the dynamic objects within the simulated virtual environment in approximate real-time.

Referring back to the example of FIG. 2, the model data 52 also includes environment models 58. The environment models 58 can be associated with environmental conditions in the simulated virtual environment, such as including weather conditions that can affect sensors and/or performance of the autonomous vehicle. Thus, the environment models 58 can enable testing of the real-world environmental conditions on the performance of the autonomous vehicle in the simulated mission. For example, the environment models 58 can be implemented to simulate the conditions of any of a variety of weather conditions (e.g., rain, snow, wind, etc.) with respect to operation of the simulated version of the autonomous vehicle (e.g., in flight), with respect to changes to coefficient of friction on takeoff and landing, with respect to changes to the effectiveness of sensors, and/or the effects on the behavior of dynamic objects. The environment models 58 can include a library that defines modeled behavior with respect to a variety of different weather conditions.

The model data 52 further includes sensor models 60. The sensor models 60 can include data associated with simulated aspects of the sensors of the autonomous vehicle. For example, the sensor models 60 can be implemented to simulate sensor responses of actual hardware sensors associated with the autonomous vehicle to transform conditions of the simulated virtual environment into actual sensor data. As an example, each sensor device associated with the autonomous vehicle can include a variety of detailed specifications, such as frame rate, resolution, field of view, dynamic range, mounting positions, and data formats. Therefore, each of the detailed specifications can be modeled and stored in the sensor models 60 to simulate the responses of the sensors of the autonomous vehicle, and thus can provide associated simulated responses for the simulated version of the autonomous vehicle. For example, the sensor models 60 can include models associated with a navigation sensor (e.g., modeled as a global navigation satellite system (GNSS) and/or inertial navigation sensor(s) (INS)), a radar system, a lidar system, a video system, electro-optical sensors, and/or a variety of other types of sensors. As described in greater detail herein, the simulation driver 20 can introduce event contingencies based on the sensor models 60 corresponding to the interaction of the autonomous vehicle in the simulated virtual environment during a simulated mission, such as defined in a test script. Therefore, by simulating raw sensor data in a simulated mission, the perception system of the actual autonomous vehicle, including all processing and data reduction components, can be tested for performance and accuracy.

In the example of FIG. 2, the memory system also includes simulation behavioral data 62. The simulation behavioral data 62 can include data associated with behavior of the moving components in the simulated virtual environment. In the example of FIG. 2, the simulation behavioral data 62 includes dynamic object behavior data 64 corresponding to the behavior of the dynamic objects in the simulated virtual environment, such as to define the parameters of the motion of vehicles (land and/or air vehicles). For example, the dynamic object behavior data 64 can define perception, reactions, communications, movement plans, and/or other behavioral aspects of the dynamic objects in the simulated virtual environment. As an example, the dynamic object behavior data 64 can include predefined action scripts associated with the behavior of the dynamic object, can include prompts to allow dynamic control of the dynamic object during a given simulated mission, such as responsive to user inputs via the user interface, and/or can include a randomization engine configured to pseudo-randomly generate dynamic behavior of the dynamic objects in the simulated virtual environment. Thus, the reactive behavior of the autonomous vehicle control system 12 with respect to controlling the autonomous vehicle can be tested under a variety of different unpredictable test scenarios.

The simulation behavioral data 62 can also include autonomous vehicle behavior (“AV BEHAVIOR”) data 66. The autonomous vehicle behavior data 66 can include data associated with the autonomous vehicle, such as including physical characteristics of the autonomous vehicle, including physical boundaries of the autonomous vehicle with respect to the static features and dynamic objects of the simulated virtual environment. The autonomous vehicle behavior data 66 can also include data associated with the interaction of the actuators of the autonomous vehicle in the simulated virtual environment. Thus, features of the autonomous vehicle, such as guidance, navigation, control capabilities, actuators, and physical dynamics of the autonomous vehicle, can be defined in the autonomous vehicle behavior data 66 to govern the movement and interaction of the autonomous vehicle through the simulated virtual environment.

Furthermore, the simulation behavioral data 62 includes physics data 68. The physics data 68 can be configured to define the physical interaction of the models 54, 56, 58, and 60 with respect to each other and to the behavior defined in the simulation behavioral data 62. The physics data 68 can thus define physical interactions of substantially all components of the simulated virtual environment. As an example, the physics data can be generated via a physics engine, such as in the simulation controller 16, which can be implemented via one or more processors associated with the simulation controller 16. Thus the physics data 68 can be generated and provided to the simulation driver 20 via the memory system 50 as needed. Additionally or alternatively, the physics data 68 can be defined by a user via the user interface 14 and stored in the memory system 50 to be implemented by the simulation driver 20 during the simulated mission. Accordingly, the physics data 68 can approximate physical interactions between substantially all portions of the simulated virtual environment to provide for an accurate simulation of the autonomous vehicle to approximate real-world operation of the autonomous vehicle.

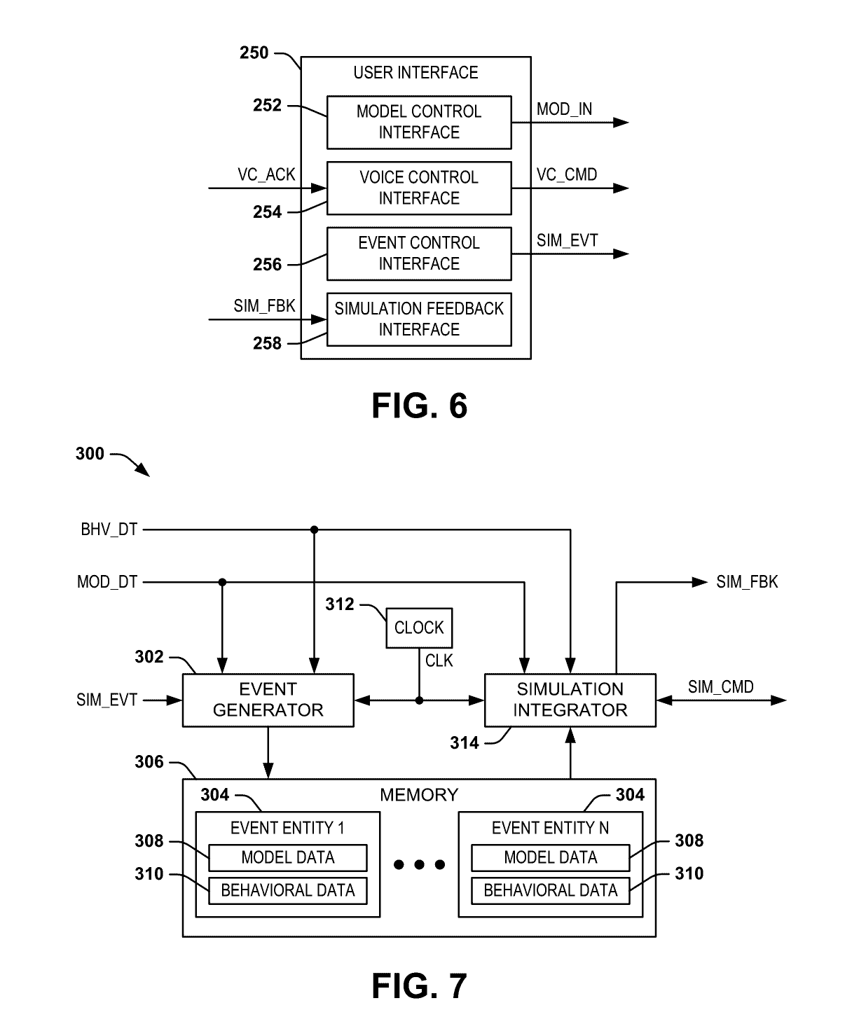

FIG. 6 illustrates an example of a user interface 250. The user interface 250 can be configured as a computer system or graphical user interface (GUI) that is accessible via a computer (e.g., via a network) to control the simulated operation of the autonomous vehicle. The user interface 250 can correspond to the user interface 14 in the example of FIG. 1. Therefore, reference is to be made to the example of FIG. 1 in the following description of the example of FIG. 1.

The user interface 250 includes a model control interface 252 that is configured to facilitate model inputs MOD_IN to the simulation controller 16. The model inputs MOD_IN can be provided to define the model data 52 and/or the simulation behavioral data 62 in the memory system 50. As an example, the model control interface 252 can be a program or application operating on the user interface 250.

The user interface 250 also includes a voice control interface 254. The voice control interface 254 is configured to receive voice audio inputs provided from a user, such as via a microphone, and to convert the voice audio inputs into control commands VC_CMD that are provided to the autonomous vehicle control system 12 (e.g., via the simulation driver 20). As an example, the control commands VC_CMD can be basic operational inputs that are provided for control of the autonomous vehicle, such that the autonomous vehicle control system 12 can respond via output signals provided to respective actuator components for motion control of the autonomous vehicle in a programmed manner. For example, the control commands VC_CMD can include commands for takeoff, landing, targeting, altitude control, speed control, directional control, or a variety of other simple commands to which the autonomous vehicle control system 12 can respond via outputs to control the autonomous vehicle based on the control programming therein. Therefore, the user of the user interface 250 can implement the simulated mission of the autonomous vehicle via the voice inputs provided to the voice control interface 254. As another example, the voice inputs can be provided to the voice control interface 254 as pre-recorded audio transmissions to allow for scripted voice scenarios of the simulated mission. Additionally, the voice control interface 254 can receive feedback signals VC_ACK from the autonomous vehicle control system 12 and convert the feedback signals to pre-recorded audio signals for interpretation by the associated user. The feedback signals VC_ACK can be status signals and/or acknowledgement signals to provide the user with sufficient information for control and/or mission parameters associated with the simulated mission. Accordingly, based on the voice control interface 254, a simulated mission of the autonomous vehicle can be initiated and completed based on implementing voice commands and audio feedback.

The user interface 250 also includes an event control interface 256 configured to facilitate event inputs SIM_EVT that can be provided to generate predetermined perturbations to the simulated virtual environment to test the reactive behavior of the autonomous vehicle control system 12 during a simulated mission. As an example, the event inputs SIM_EVT can be provided as Extensible Markup Language (XML) scripts. The event control interface 256 can be implemented to provide the event inputs SIM_EVT before a simulated mission or during a simulated mission, such as to control the conditions of the simulated virtual environment, such as with respect to the dynamic objects and/or the environment conditions (e.g., simulated weather conditions). As an example, the event inputs SIM_EVT can correspond to scripted events (e.g., time-based), can correspond to spontaneous events provided by the user, or can initiate random events (e.g., generated randomly via the simulation driver 20). Thus, the autonomous vehicle control system 12, in controlling the simulated version of the autonomous vehicle, can be tested for improvised reactive behavior to the events that are defined via the event inputs SIM_EVT based on the programming therein.

The user interface 250 further includes a simulation feedback interface 258. The simulation feedback interface 258 is configured to receive feedback signals SIM_FBK that can be provided, for example, from the simulation driver 20 to enable user(s) to monitor the simulated operation of the autonomous vehicle, such as in real-time. As an example, the simulation feedback interface 258 can include a monitor or a set of monitors that can display the simulated virtual environment in real-time during the simulated mission, such as to simulate video camera or other imaging sensor feed(s) to monitor the simulated interaction of the autonomous vehicle in the simulated virtual environment. For example, the monitor of the simulation feedback interface 258 can display simulated video images, radar images, lidar images, or a combination thereof. The user(s) can thus view the simulated virtual environment in a variety of different ways, such as overhead (e.g., as demonstrated by the diagram 100 in the example of FIG. 3), or in a “fly-through” mode to simulate a view of imaging equipment on-board the autonomous vehicle. Thus, the user(s) can provide voice commands VC_CMD and/or event inputs SIM_EVT in real-time during the simulated mission to control the autonomous vehicle and/or to provide spontaneous perturbations of the simulated virtual environment via the voice control interface 254 and/or the event control interface 256, respectively, and monitor the responses and reactive behavior of the simulated version of the autonomous vehicle via the simulation feedback interface 258 based on the feedback signals SIM_FBK. Furthermore, the simulation feedback interface 258 can be configured to record the simulated mission to generate an event log that is saved in a memory (e.g., the memory system 50). Thus, the simulated mission can be viewed and reviewed a number of times from start to finish, or at portions in between, at any time subsequent to completion of the simulated mission.

FIG. 7 illustrates an example of a simulation driver 300. The simulation driver 300 is configured to receive the inputs from a user interface (e.g., the user interface 250) and to integrate the inputs and the model and simulation behavioral data stored in a memory system (e.g., the memory system 50) to provide simulation signals to and receive feedback signals from the autonomous vehicle control system 12. The simulation driver 300 can correspond to the simulation driver 20 in the example of FIG. 1. Therefore, reference is to be made to the example of FIG. 1, as well as the examples of FIGS. 2 and 6, in the following description of the example of FIG. 7.

The simulation driver 300 includes an event generator 302 that is configured to generate event entities 304 corresponding to dynamic events in the simulated virtual environment during the simulated mission, and stores the event entities 304 in a memory 306. As an example, the memory 306 can correspond to the memory system 50 in the example of FIG. 2. The memory 306 is demonstrated as storing a plurality N of event entities 304, with N being a positive integer. Each of the event entities 304 is demonstrated as including model data 308 and behavioral data 310 associated with the respective one of the event entities 304. Therefore, each respective one of the event entities 304 includes data that dictates how it is physically modeled and how it behaves in the simulated virtual environment.

In the example of FIG. 7, the event generator 302 receives the event inputs SIM_EVT corresponding to the creation of a given event. The event can be any of a variety of examples of perturbations or changes to the simulated virtual environment, such as movement of one or more dynamic objects, weather changes, or any other alteration of the simulated virtual environment with respect to the dynamic objects or environment conditions of the simulated virtual environment. For example, given events that can be generated by the event generator 302 in response to the event inputs SIM_EVT can include takeoff and/or landing of aircraft in the simulated virtual version of Hawthorne Municipal Airport, movement of ground vehicles across the runway, changes to weather conditions, or a variety of other types of events that can affect operation of the simulated version of the autonomous vehicle (e.g., being under fire by or being commanded to attack simulated hostiles in a combat simulation). The event generator 302 also receives model data MOD_DT that can be provided from the memory system 50, such as including dynamic models 56 and/or the environment models 58, as well as the scene models 52 to provide a relative location associated with the event (e.g., the associated dynamic object) in the simulated virtual environment. Thus, the model data MOD_DT provides the model data 308 stored and associated with the respective event entity 304. Similarly, the event generator 302 also receives simulation behavioral data BHV_DT that can be provided from the memory system 50, such as from the simulation behavioral data 62 that can define the dynamic behavior associated with the event (e.g., motion of the dynamic object). Thus, the simulation behavioral data BHV_DT provides the behavioral data 310 stored and associated with the respective event entity 304. Additionally, in the example of the event being a scripted event, such as to occur at a later time during the simulated mission, the event generator 302 also generates a time stamp based on a clock signal CLK that is provided via a clock 312. As an example, the clock 304 can be and/or can mimic a clock associated with GNSS or an INS associated with the autonomous vehicle. As described herein, the behavioral data 310, and thus also the time stamp(s) associated with the event entities 304, can be defined by the user(s) via the user interface 250, or can be randomly generated to provide unpredictability with respect to the event entities 304.

The simulation driver 300 also includes a simulation integrator 314 that is configured to integrate the event entities 304 into the simulated virtual environment. The simulation integrator 314 receives the clock signal CLK and the model data MOD_DT from the memory system 50, such as the scene models 54. Thus, at an appropriate time dictated by the a comparison of real-time (via the clock signal CLK) with the time stamp associated with the event entity 304, or in substantial real-time, the simulation integrator 314 can access the appropriate event entity 304 and provide the necessary integration of the associated event in the simulated virtual environment. The simulation integrator 314 can integrate the event entity 304 into the simulated virtual environment by compiling the model data 308 and behavioral data 310 with the scene models 54 to provide the associated dynamic activity relative to the static features of the simulated virtual environment at the appropriate time. Additionally, the simulation integrator 314 can access the sensor models 60 to translate the event entity 304 into sensor data, such as to simulate raw sensor data of sensors on-board the actual autonomous vehicle, that can be interpreted by the autonomous vehicle control system 12.

In the example of FIG. 7, the interaction of the simulation integrator 314 with the autonomous vehicle control system 12 is demonstrated as bidirectional signals SIM_CMD demonstrating the transfer of the simulated sensor signals to the autonomous vehicle control system 12. Additionally, the signals SIM_CMD can include output signals provided from the autonomous vehicle control system 12 corresponding to the control of autonomous vehicle and the reactive behavior of the autonomous vehicle control system 12 in response to the simulated sensor data, and thus the reaction to the events defined by the event entities 304. For example, the output signals from the autonomous vehicle control system 12 can correspond to outputs to actuators or other devices associated with the autonomous vehicle, such as to control the movement, behavior, and/or reactions of the autonomous vehicle.

The simulation integrator 314 can thus provide the simulation feedback signals SIM_FBK to simulate the results of the outputs provided from the autonomous vehicle control system 12, such as based on the autonomous vehicle behavior data 66 and the physics data 68 that can be provided via the simulation behavioral data BHV_DT that can be provided from the memory system 50. As described previously, the simulation feedback signals SIM_FBK can be provided to the user interface 250 (e.g., the simulation feedback interface 258), such that user(s) can monitor the movement, behavior, and/or reactions of the autonomous vehicle, and thus the simulated operation of the autonomous vehicle. Accordingly, based on the operation of the simulation driver 300, user(s) can monitor the simulated interaction of the autonomous vehicle in the simulated virtual environment, including the reactive behavior of the autonomous vehicle to the perturbations of the simulated virtual environment provided by the event entities 304 to provide for accurate testing of the programmed control of the autonomous vehicle via the autonomous vehicle control system 12.

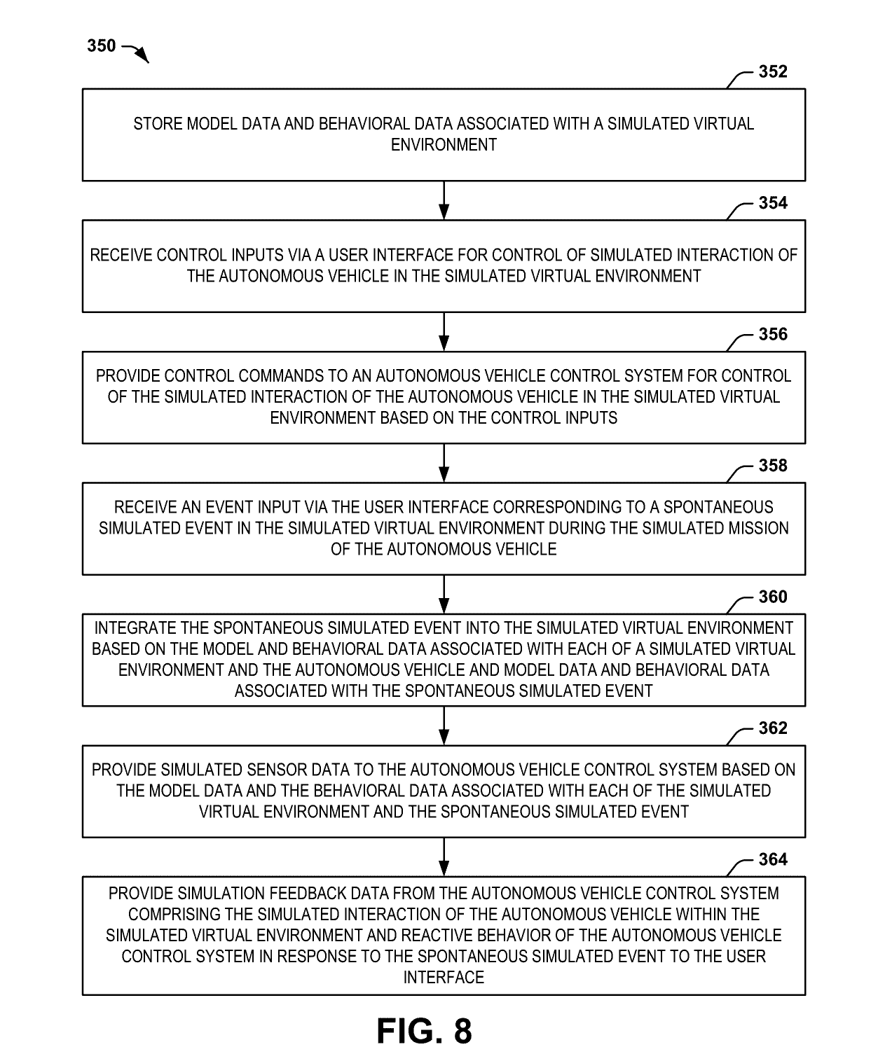

In view of the foregoing structural and functional features described above, a methodology in accordance with various aspects of the present invention will be better appreciated with reference to FIG. 8. While, for purposes of simplicity of explanation, the methodology of FIG. 8 is shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect of the present invention.

FIG. 8 illustrates an example of a method 350 for simulating a mission for an autonomous vehicle. At 352, model data (e.g., the model data 52) and behavioral data (e.g., the simulated behavioral data 62) associated with a simulated virtual environment are stored. At 354, control inputs (e.g., the voice commands) are provided via a user interface (e.g., the user interface 14) for control of simulated interaction of the autonomous vehicle in the simulated virtual environment. At 356, providing control commands (e.g., the voice control commands VC_CMD) to an autonomous vehicle control system (e.g., the autonomous vehicle control system 12) for control of the simulated interaction of the autonomous vehicle in the simulated virtual environment based on the control inputs. At 358, an event input (e.g., the event inputs SIM_EVT) is received via the user interface corresponding to a spontaneous simulated event in the simulated virtual environment during the simulated mission of the autonomous vehicle.

At 360, the spontaneous simulated event (e.g., an event entity 304) is integrated into the simulated virtual environment based on the model and behavioral data associated with each of a simulated virtual environment and the autonomous vehicle and model data (e.g., the model data 308) and behavioral data (e.g., the behavioral data 310) associated with the spontaneous simulated event. At 362, simulated sensor data (e.g., the signals SIM_CMD) is provided to the autonomous vehicle control system based on the model data and the behavioral data associated with each of the simulated virtual environment and the spontaneous simulated event. At 364, simulation feedback data (e.g., the signals SIM_CMD from the simulated autonomous control system 12 and the simulation feedback signals SIM_FBK) is received from the autonomous vehicle control system comprising the simulated interaction of the autonomous vehicle within the simulated virtual environment and reactive behavior of the autonomous vehicle control system in response to the spontaneous simulated event.

What have been described above are examples of the invention. It is, of course, not possible to describe every conceivable combination of components or methodologies for purposes of describing the invention, but one of ordinary skill in the art will recognize that many further combinations and permutations of the invention are possible. Accordingly, the invention is intended to embrace all such alterations, modifications, and variations that fall within the scope of this application, including the appended claims.

What is claimed is:

1. A simulation system for an autonomous vehicle, the simulation system comprising:
a user interface configured to facilitate user inputs comprising spontaneous simulated events in a simulated virtual environment during simulated operation of the autonomous vehicle via an autonomous vehicle control system; and
a simulation controller configured to generate simulated sensor data based on model data and behavioral data associated with each of the simulated virtual environment and the spontaneous simulated events, the simulated sensor data corresponding to simulated sensor inputs provided to the autonomous vehicle control system via sensors of the autonomous vehicle, and further configured to receive simulation feedback data from the autonomous vehicle control system corresponding to simulated interaction of the autonomous vehicle within the simulated virtual environment, the simulated interaction comprising reactive behavior of the autonomous vehicle control system in response to the spontaneous simulated events.

2. The system of claim 1, wherein the simulation controller comprises a memory configured to store model data comprising:
dynamic models in the simulated virtual environment;
scene models associated with static physical features of the simulated virtual environment;
environment models associated with effects of environmental conditions on the simulated virtual environment; and
sensor models corresponding to the simulated sensor data as a function of the simulated virtual environment, the dynamic models, the scene models, and the environment models.

3. The system of claim 2, wherein the user interface comprises a model control interface configured to facilitate the user inputs to at least one of generate and define parameters associated with at least one of the dynamic models, the scene models, the environment models, and the sensor models.

4. The system of claim 1, wherein the simulation controller comprises a memory configured to store simulation behavioral data comprising:
dynamic object behavior data corresponding to operational behavior of dynamic models in the simulated virtual environment;
autonomous vehicle behavior data corresponding to physical parameters and behavior of the simulated interaction of the autonomous vehicle within the simulated virtual environment; and
physics data configured to define physical parameters of the simulated interaction of the autonomous vehicle with the simulated virtual environment.

5. The system of claim 4, wherein the user inputs are configured to facilitate randomization of the dynamic object behavior data associated with random operational behavior of the dynamic models in the simulated virtual environment.

6. The system of claim 1, wherein the user interface comprises a voice control interface configured to receive the user inputs as voice commands, to convert the voice commands into control commands for control of the simulated interaction of the autonomous vehicle in the simulated virtual environment via the autonomous vehicle control system.

7. The system of claim 6, wherein the voice control interface is further configured to convert at least a portion of feedback signals provided by the autonomous vehicle control system associated with the simulated interaction of the autonomous vehicle in the simulated virtual environment to audio signals for interpretation by an associated user.

8. The system of claim 1, wherein the user interface further comprises an event control interface configured to facilitate receipt of the user inputs during the simulated operation of the autonomous vehicle as event inputs corresponding to the spontaneous simulated events corresponding to dynamic conditions of the simulated virtual environment, wherein the simulation controller comprises a simulation driver configured to generate at least one event entity based on the model data, the behavioral data, the event inputs, and a clock signal; to integrate the at least one event entity into the simulated virtual environment; and to integrate reactive outputs from the autonomous vehicle control system corresponding to control of the autonomous vehicle into the simulated interaction of the autonomous vehicle in the simulated virtual environment.

9. The system of claim 1, wherein the user interface comprises a simulation feedback interface configured to display the simulated interaction of the autonomous vehicle in the simulated virtual environment and to facilitate the user inputs comprising control commands for control of the simulated interaction of the autonomous vehicle in the simulated virtual environment via the autonomous vehicle control system.

10. The system of claim 9, wherein the simulation feedback interface is further configured to record the simulated operation of the autonomous vehicle comprising the simulated interaction of the autonomous vehicle in the simulated virtual environment to generate an event log comprising a simulated mission of the autonomous vehicle.

11. A non-transitory computer readable medium that is executed to implement a method for simulating a mission for an autonomous vehicle, the method comprising:
storing model data and behavioral data associated with a simulated virtual environment;
receiving control inputs via a user interface for control of simulated interaction of the autonomous vehicle in the simulated virtual environment;
providing control commands to an autonomous vehicle control system for control of the simulated interaction of the autonomous vehicle in the simulated virtual environment based on the control inputs;
receiving an event input via the user interface corresponding to a spontaneous simulated event in the simulated virtual environment during the simulated mission of the autonomous vehicle;
integrating the spontaneous simulated event into the simulated virtual environment based on the model and behavioral data associated with each of a simulated virtual environment and the autonomous vehicle and model data and behavioral data associated with the spontaneous simulated event;
providing simulated sensor data to the autonomous vehicle control system based on the model data and the behavioral data associated with each of the simulated virtual environment and the spontaneous simulated event; and
providing simulation feedback data from the autonomous vehicle control system comprising the simulated interaction of the autonomous vehicle within the simulated virtual environment and reactive behavior of the autonomous vehicle control system in response to the spontaneous simulated event to the user interface.

12. The medium of claim 11, wherein storing the model data and the behavioral data comprises:
storing dynamic model data associated with at least one dynamic model in the simulated virtual environment;
storing scene model data associated with static features of the simulated virtual environment;
storing environment model data associated with effects of environmental conditions on the simulated virtual environment, the spontaneous simulated event being associated with at least one of the at least one dynamic object and the environmental conditions; and
sensor models corresponding to the simulated sensor data as a function of the simulated virtual environment, the dynamic model, and the environment conditions.

13. The medium of claim 11, wherein storing the model data and the behavioral data comprises:
storing dynamic object behavior data corresponding to operational behavior of at least one dynamic model in the simulated virtual environment;
storing autonomous vehicle behavior data corresponding to physical parameters and behavior of the simulated interaction of the autonomous vehicle within the simulated virtual environment; and
storing physics data configured to define physical parameters of the simulated interaction of the autonomous vehicle with the simulated virtual environment.

14. The medium of claim 11, wherein receiving the control inputs comprises receiving voice commands, the method further comprising converting the voice commands into the control commands.

15. The medium of claim 14, further comprising:
converting at least a portion of the simulation feedback data provided by the autonomous vehicle control system associated with the simulated interaction of the autonomous vehicle in the simulated virtual environment into audio signals; and
providing the audio signals at the user interface for interpretation by an associated user.

16. The medium of claim 11, further comprising displaying the simulated interaction of the autonomous vehicle in the simulated virtual environment via the user interface, wherein receiving the control inputs comprises receiving the control inputs via the displayed simulated interaction of the autonomous vehicle in the simulated virtual environment.

17. A simulation system for an autonomous vehicle, the simulation system comprising:
a user interface configured to facilitate user inputs comprising spontaneous simulated events in a simulated virtual environment during simulated operation of the autonomous vehicle via an autonomous vehicle control system, and to record a simulated interaction of the autonomous vehicle in the simulated virtual environment to generate an event log comprising a simulated mission of the autonomous vehicle; and
a simulation controller comprising:
a memory configured to store model data and behavior data associated with the simulated virtual environment; and
a simulation driver configured to generate at least one event entity based on the model data, the behavioral data, the user inputs, and a clock signal; to integrate the at least one event entity into the simulated virtual environment; to provide simulated sensor data based on the model and behavioral data associated with each of the simulated virtual environment and the at least one event entity, and to receive simulation feedback data from the autonomous vehicle control system corresponding to the simulated interaction of the autonomous vehicle within the simulated virtual environment, the simulated interaction comprising reactive behavior of the autonomous vehicle control system in response to the at least one event entity.

18. The system of claim 17, wherein the model data comprises:
dynamic models in the simulated virtual environment;
scene models associated with static features of the simulated virtual environment;
environment models associated with effects of environmental conditions on the simulated virtual environment; and
sensor models corresponding to the simulated sensor data as a function of the simulated virtual environment, the dynamic models, the scene models, and the environment models;
wherein the behavioral data comprises:
dynamic object behavior data corresponding to operational behavior of dynamic models in the simulated virtual environment;
autonomous vehicle behavior data corresponding to physical parameters and behavior of the simulated interaction of the autonomous vehicle within the simulated virtual environment; and
physics data configured to define physical parameters of the simulated interaction of the autonomous vehicle with the simulated virtual environment.

19. The system of claim 17, wherein the user interface comprises a voice control interface configured to receive the user inputs as voice commands, to convert the voice commands into control commands for control of the simulated interaction of the autonomous vehicle in the simulated virtual environment via the autonomous vehicle control system.

20. The system of claim 19, wherein the voice control interface is further configured to convert at least a portion of feedback signals provided by the autonomous vehicle control system associated with the simulated interaction of the autonomous vehicle in the simulated virtual environment to audio signals for interpretation by an associated user.
